(19) United States
(12) Patent Application Publication
(10) Pub. No.: US 2008/0253214 A1
(43) Pub. Date: Oct. 16, 2008

(54) Method and apparatus for incorporating DDR SDRAM into portable devices

(75) Inventors: Marc M. Stimak, Austin, TX (US); Terry C. Brown, Austin, TX (US); Daniel Benkman, Austin, TX (US)

Correspondence Address: FORTKORT & HOUSTON P.C., 9442 N. CAPITAL OF TEXAS HIGHWAY, ARBORETUM PLAZA ONE, SUITE 500, AUSTIN, TX, 78759, US

(73) Assignee: Xware Technology, Inc., Austin, TX (US)

(21) Appl. No.: 11/784,570

(22) Filed: Apr. 5, 2007

(51) Int. Cl. G06F 1/08; G11C 5/14; G11C 8/18

(52) U.S. Cl. 365/227

(57) ABSTRACT

A portable electronic device is provided which comprises (a) a memory device (42) equipped with an interface clock which is controlled by a Delay Locked Loop (DLL) such that the memory device is configured to operate in a first mode characterized by a minimum clock rate CRₘᵢₙ; and (b) a controller (38) adapted to cause the memory device to operate in a second mode by disabling the DLL, wherein the second mode is characterized by a nonzero clock rate R_{c}<CRₘᵢₙ.

### FIELD OF THE DISCLOSURE

The present disclosure relates generally to low power portable electronic devices, and more particularly to methods for reducing the power consumption of high performance memory devices to levels suitable for portable electronic devices.

### BACKGROUND OF THE DISCLOSURE

Portable electronic devices, such as mobile phones, personal media players, digital music players, digital cameras, and portable computing devices, often require fast random access memory (RAM) for temporary storage of programs and data. The provision of a large amount of RAM in such a device may enable the device to offer more advanced features, since RAM typically has higher performance characteristics than hard disk drives, flash memory, and other types of data storage media.

However, in order to be suitable for mass produced portable electronic devices, any RAM intended for use in these devices should be low cost, and should consume very little power. Many portable electronic devices currently known to the art rely on SRAM (static random access memory). Some of these devices also utilize customized forms of SDRAM (synchronous dynamic random access memory) which have been specifically designed for lower power consumption. Both of these options are relatively expensive, and therefore limit the amount of RAM that can be cost effectively provided in these devices.

The cost of standard DRAM (dynamic random access memory) chips can vary widely over time, and is driven by different market forces than those governing SRAM or versions of SDRAM which have been customized for low power consumption. Thus, standard DRAM, and in particular, DDR (double data rate) SDRAM, is currently being manufactured as a mainstream memory technology for the personal computer (PC) market, and hence is produced in large quantities by a variety of manufacturers. Consequently, these chips are available at commodity pricing levels which are typically significantly lower than the pricing levels available for SRAM or for customized versions of SDRAM. In light of this cost advantage, it would be desirable to incorporate DDR SDRAM into current generations of electronic portable devices.

Unfortunately, despite the cost advantages currently associated with DDR SDRAM, these chips are not currently compatible with the needs of the portable electronics marketplace. In particular, portable electronic devices are subject to stringent power consumption requirements. This is due, in part, to recharge considerations, weight issues, heat dissipation requirements, and a variety of other factors which govern handheld electronic devices. Since DDR SDRAM memories are designed for use in PCs and other high performance devices, they consume too much power during normal operation to make them suitable for use in portable electronic devices. Moreover, the normal operation of DDR SDRAM memories would put unnecessary design requirements on both the memory interface and the board design of a typical portable electronic device.

There is thus a need in the art for a method for rendering DDR SDRAM memories suitable for use in portable electronic devices. In particular, there is a need in the art for a method for reducing the power consumption of DDR SDRAM memory. There is further a need in the art for a means for mitigating the design requirements which incorporation of DDR SDRAM memories into a portable electronic device would typically entail. These and other needs may be met by the devices and methodologies disclosed herein.

### BRIEF DESCRIPTION OF THE DISCLOSURE

In one aspect, a method is provided herein for adapting the operation of a memory device such as, for example, a DDR SDRAM device. In accordance with the method, a memory device is provided which is equipped with an interface clock which is controlled by a Delay Locked Loop (DLL) such that the memory device is configured to operate in a first mode characterized by a minimum clock rate CRₘᵢₙ. The device is then operated in a second mode by disabling the DLL, wherein the second mode is characterized by a nonzero clock rate R_{c}<CRₘᵢₙ. Preferably, the second mode is associated with a lower power consumption level which is suitable for the requirements of portable electronic devices. Hence, this method may be used to convert a DDR SDRAM device originally designed for use in a PC so that it may be used in a portable electronic device.

In another aspect, a portable electronic device is provided which comprises (a) a memory device equipped with an interface clock and a Delay Locked Loop (DLL) such that the memory device is configured to operate in a first mode characterized by a minimum clock rate CRₘᵢₙ; and (b) a controller adapted to cause the memory device to operate in a second mode by disabling the DLL, wherein the second mode is characterized by a nonzero clock rate R_{c}<CRₘᵢₙ.

In still another aspect, a method is provided for providing dynamic clock management in a portable electronic device which incorporates DDR SDRAM. In accordance with the method, a READ loop is performed until a predetermined signature value is read and verified indicating that the DLL is locked, thereby allowing for DLL re-lock of the memory device. Preferably, the DLL is enabled and reset without having to undergo multiple NOP or DESELECT cycles prior to DLL re-lock.

### BRIEF DESCRIPTION OF THE DRAWINGS

The present disclosure is illustrated by way of example, and not by way of limitation, in the following Figures, in which like reference numerals refer to similar elements.

FIG. 1 is a block diagram of a battery-powered device in accordance with the teachings herein which incorporates DDR SDRAM;

FIG. 2 depicts a sample READ then WRITE timing diagram of a prior art interface to a DDR SDRAM;

FIG. 3 depicts a sample READ then WRITE timing diagram of an interface to DDR SDRAM in accordance with the teachings herein;

FIG. 4 depicts a process flow of a method in accordance with the teachings herein for switching DDR SDRAM from a low power mode, DLL disabled state to a high performance mode, DLL enabled state; and

FIG. 5 depicts a process flow in accordance with the teachings herein for switching DDR SDRAM from a low power mode, DLL disabled state to a high performance mode, DLL enabled state.

### DETAILED DESCRIPTION

It has now been found that the foregoing needs in the art may be met by operating a memory device (which is preferably a DRAM, and more preferably a DDR SDRAM) in a low power mode commensurate with the requirements of portable electronic devices. This may be accomplished by disabling the Delay Locked Loop (DLL) in the memory device, and by operating the interface between the memory device and the host device at lower than normal asynchronous clock rates in order to keep power consumption low when high speed performance of the memory device is not required.

The speed of the interface will be determined by the portable device bandwidth requirements but, in many cases, will be significantly less than the minimum operating frequency of the DDR SDRAM with the DLL enabled. The reduction in interface speed results in a corresponding reduction in power consumption. Additional power conservation may be achieved by issuing clocks to the DDR SDRAM only as needed for read, write, or refresh cycles. Suitable methods for issuing such clocks are described in greater detail in U.S. Ser. No. 10/256,265 (Stimak et al.), entitled “Dynamic Memory Management”, which was filed on Sep. 26, 2002, and which is incorporated herein by reference in its entirety.

In a preferred embodiment of the systems and methodologies disclosed herein, a means is provided for effectively switching between a low power mode, where the DLL of the DDR SDRAM is disabled and the interface is operated at lower than normal asynchronous clock speeds, and a high performance mode, where the DLL of the DDR SDRAM is quickly re-enabled and reset, thus allowing for operations up to the rated maximum clock speed of the DDR SDRAM as determined by the bandwidth requirements of the portable electronic device. This method of quickly re-enabling the DLL of the DDR SDRAM provides for complete clock speed control from zero MHz up to the rated maximum clock speed of the DDR SDRAM. Such a capability enables system designers to utilize standard PC DDR SDRAM in a power and cost effective manner in portable electronic devices, thus offering a more flexible system design with respect to power and performance management.

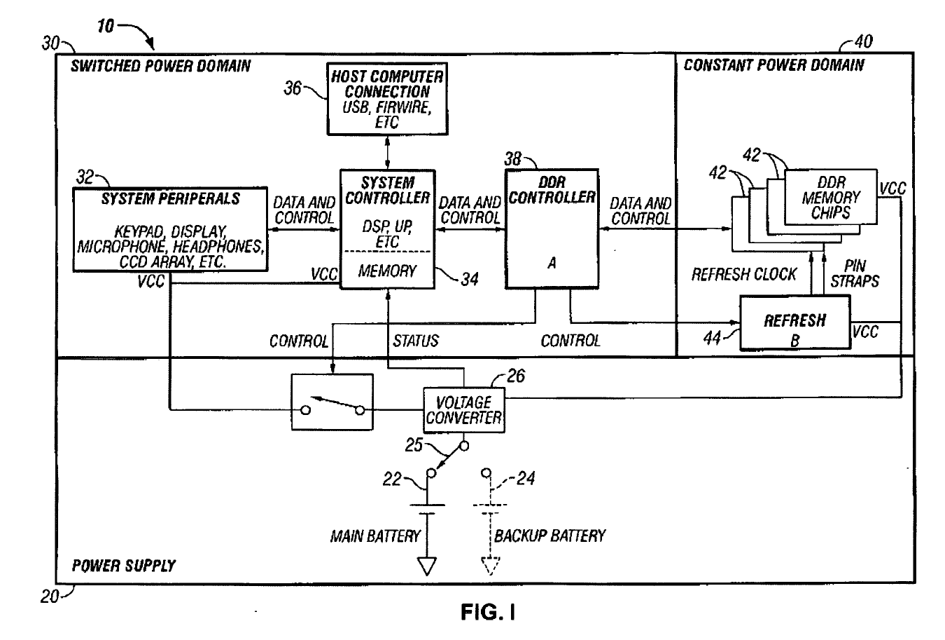

FIG. 1 illustrates a first particular, non-limiting embodiment of a battery powered portable electronic device 10 made in accordance with the teachings herein. The device 10 comprises a power supply 20, including a main battery 22, a backup battery 24, and a voltage converter 26. The device 10 further comprises a switched power domain 30, including system peripherals 32, a system controller 34, a host computer connection 36, and an SDRAM controller 38. The device 10 also comprises a constant power domain 40, including DDR memory chips 42 and a refresh clock controller 44.

Power to the device 10 is provided by either a main battery 22 or backup battery 24, depending on the position of switch 25. In either case, the “battery” may be a single battery or a plurality of batteries. If a plurality of batteries are used, the batteries may be connected in series or in parallel.

The backup battery 24 is used to maintain power supply to the constant power domain 40 when the main battery 22 is replaced, or when any other short-term power supply is needed. In some embodiments of the systems and methodologies described herein, the main battery 22 may be a rechargeable-type battery, and the backup battery 24 is not installed. In such embodiments, the power supply used to recharge main battery 22 is further used to provide power to the constant power domain 40. The power switch 25 may be mechanically or electrically activated.

The switched power domain 30 contains a system controller 34, system peripherals 32, a host computer connection 36, and an SDRAM controller 38. The power requirements of each of these elements are considered secondary to the power requirements of the constant power domain 40.

The system controller 34 interacts with all elements in the switched power domain 30 to operate battery-powered device 10. As one of its processes, the system controller 34 determines when elements not located in the constant power domain 40 must be powered down. If the system controller 34 determines the power level to be too low to maintain the current in the battery-powered device 10, all elements in the switched power domain 30 are switched to a powered down or inactive mode until the power level rises above the threshold. When the device is in a powered up mode, the system controller 34 generates an asynchronous clock signal to issue read, write, and refresh cycle instructions. The system controller 34 issues the clock signals required for each instruction and does not issue clock signals when the device 10 is in a powered down mode. The system controller 34 issues refresh cycle instructions at a minimal rate, similar to the method used to refresh SDRAM memory chips 42 when device 10 is in a powered down mode. The refresh cycle instructions may be auto refresh or self refresh. These instructions may be issued periodically, or may be issued in bursts or groups such that each internal row of SDRAM memory is refreshed to avoid memory loss.

The system peripherals 32 may include, without limitation, any device for interacting with battery-powered device 10. Such devices may include, for example, keypads, displays, microphones, headphones, and CCD arrays.

The host computer connection 36 connects the battery-powered device 10 to a host computer to download files, music, or other information. The host computer connection 36 may be USB, Firewire, or any other connection without departing in scope from the present invention. The host computer (not shown) may also be used as a backup system. In some embodiments, the host computer saves a copy of the information downloaded to battery-powered device 10, so that the contents of SDRAM memory chips 42 may be recovered in the event of power loss in the battery-powered device 10.

The DDR controller 38 controls the interface to the DDR chips 42 during active modes. The DDR controller 38 issues read, write, and refresh cycle instructions as requested by the system controller 34. In some embodiments, the DDR controller 38 issues read, write, and refresh cycle instructions using an asynchronous clocking scheme. The DDR controller 38 also controls the active mode chip partitioning for storage of information. Although the DDR controller 38 and the system controller 34 are shown as separate elements, all or portions of the DDR controller 38 may be implemented in software depending on the capabilities of system controller 34. In the event that the power level drops below a specified threshold, the DDR controller 38 may configure DDR memory chips 42 for refresh cycle operations before system controller 34 powers down the switched power domain 30.

The constant power domain 40 contains one or more DDR memory chips 42 and a refresh clock controller 44, also referred to as a refresh circuit. Refresh clock controller 44 controls the DDR memory chips 42 during periods in which switched power domain elements are powered down. In some embodiments, the refresh clock controller 44 may configure the one or more DDR memory chips 42 for refresh commands using pin straps and may issue clock signals to initiate refresh cycles.

In a preferred embodiment, the clock signal rate and the refresh rate during device powered down states are constant, and the clock is enabled/disabled by the DDR controller 38. However, the clock signal rate may be adjustable so that the minimal refresh rate may be determined for each battery-powered device 10. In device powered up states in some embodiments, the clock signal is non-periodic or may be supplied only when read, write, or refresh cycle operations are required. A non-periodic clock signal enables the minimum number of clock signals to be issued, resulting in minimal power consumption. In a preferred embodiment, the active mode configuration of the digital clock is asynchronous, non-periodic, and supplied to the DDR memory chips 42 only when read, write, or refresh cycle instructions are supplied to the system controller 34. In this embodiment, active power consumption is reduced by reducing the number of times the DDR memory chips 42 are accessed.

In the device depicted in FIG. 1, the DDR SDRAM 42 operates in much the same way as the previous generation of single data rate or SDR SDRAM. The interface of both RAM types includes a set of control signals and a data bus, DQ, that are synchronized to an interface clock, CK. The interface clock for DDR is normally implemented as a differential pair, CK and CK. For simplicity, however, it will be referred to herein as CK. Both SDRAM types receive commands from the RAM controller on the rising edge of the CK. The key difference between the two types of SDRAM is that DDR SDRAM supports data transfers on the DQ using both the rising and falling edges of the interface clock CK, while SDR SDRAM only supports data transfers on the rising edge. This difference allows a DDR SDRAM to support approximately twice the bandwidth of an SDR SDRAM running at the same clock speed. For both memory types, the DQ bus is bidirectional. It is driven by the RAM controller during a write operation, and by the SDRAM during a READ operation. DDR SDRAMs also include a data strobe signal, DQS. For WRITE operations, this signal is driven by the RAM controller, and both the rising and falling edges are used by the DDR SDRAM to capture the incoming data. For read operations, the DDR SDRAM drives the DQS signal along with DQ on both the rising and falling edge of CK.

Since DDR SDRAMs operate at high speed and use both clock edges, they include an internal DLL that is used to align the data transfers on DQ and DQS to the interface clock. The DLL can be enabled or disabled by a control bit in the Extended Mode Register of the DDR SDRAM. The system controller can write to the Extended Mode Register by issuing the Mode Register Set command on the rising edge of CK. For normal high speed operation, the DLL must be enabled so that the interface timing requirements of DQ and DQS can be met.

When the DLL is first enabled, it must be allowed to run for some time in order to lock to the frequency and phase of CK before any read or write operations can occur. A typical DDR SDRAM specification will require 200 clocks to ensure worst case for the DLL to lock. In accordance with the preferred embodiment of the devices and methodologies disclosed herein, the DDR SDRAMs are operated with the DLL disabled in order to reduce the power consumption of the DDR SDRAM. This removes the requirement for a continuously running CK.

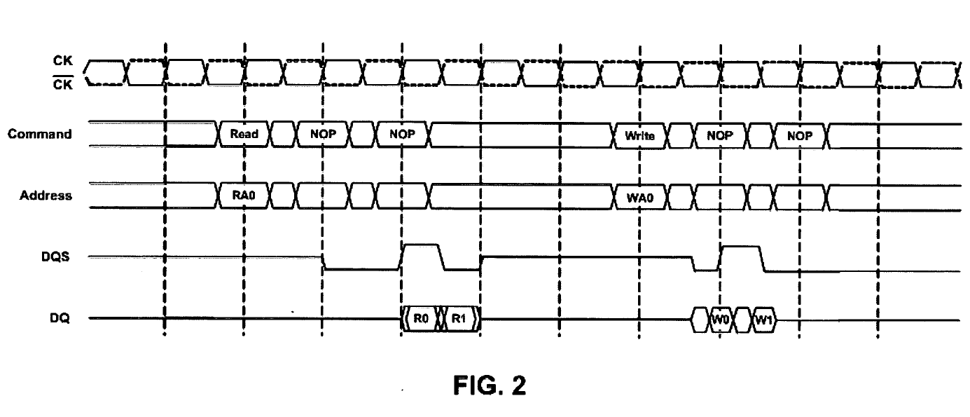

FIG. 2 is a simplified timing diagram which illustrates a DDR SDRAM READ cycle followed by a WRITE cycle for a conventionally operated DDR SDRAM. The diagram does not show the steps required to prepare the DDR SDRAM for READ and WRITE commands. Rather, it is only intended to show the relative timing of the DQ, DQS, and CK signals.

The CK clock signal is a continuous differential clock that is driven by the RAM controller to the DDR SDRAM. The RAM controller also drives the command and address signals so that they are valid on the rising edges of CK. When the DDR SDRAM is ready to present the data from a READ command, it drives the data on DQ and the strobe on DQS. These signals are driven on both the rising and falling edge of CK. When the RAM controller issues a WRITE command to the DDR SDRAM, it drives the data on DQ at the appropriate time. The controller also drives the DQS such that it transitions during a time in which the data on DQ is valid. Therefore, the DDR SDRAM will capture the data on DQ only when the DQS transitions.

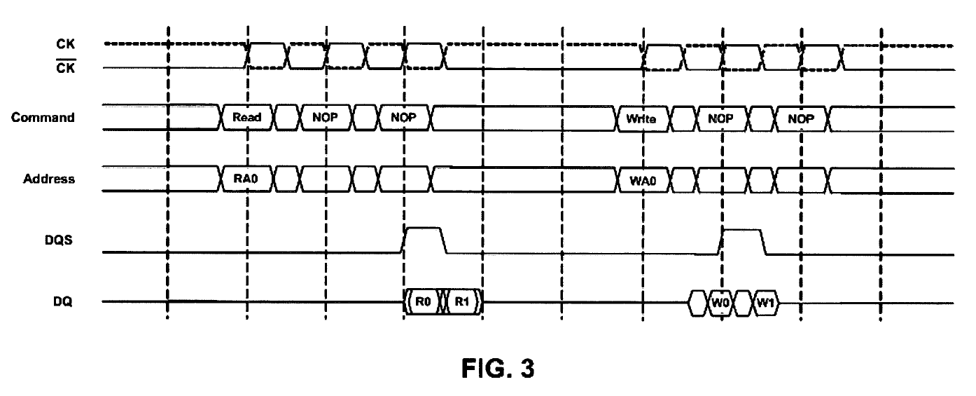

FIG. 3 is a simplified timing diagram which illustrates a DDR SDRAM READ cycle followed by a WRITE cycle for a DDR SDRAM operated in accordance with a particular, non-limiting embodiment of the methodology disclosed herein. In contrast to the operation depicted in FIG. 2, the clock signal CK in the operation depicted in FIG. 3 is not continuous. Rather, the clock only transitions when it is needed to issue a command or to activate the internal pipeline of the DDR SDRAM for a READ or WRITE command.

Other DDR SDRAM commands, such as ACTIVE, NOPS PRECHARGE, and other such commands, are not shown in the diagram. The RAM controller will issue the minimum number of clocks needed to complete those operations in the same manner as the READ and WRITE commands shown in FIG. 3. The relative timing of the signal edges shown in FIG. 2 are maintained for correct operation of the DDR SDRAM. However, the signals are no longer driven at the constant intervals provided by a continuous clock, and the actual timing may vary greatly from the timing attendant to the operation depicted in FIG. 2. In some embodiments of the devices and methodologies disclosed herein, the DDR SDRAM controller may issue one or more “no operation” (NOP) commands after completing a READ or WRITE command. These NOP commands are used to put the DDR SDRAM pipeline into a known state in preparation for the next set of commands.

In order for the DDR SDRAM to work correctly with the timing in FIG. 3, the internal DLL must be disabled. Disabling the DLL has the added benefit of reducing the power consumption of the DDR SDRAM. Also, the DLL lock time (200 clock cycles) is avoided during startup or other times when the DLL would normally be enabled. Some DDR SDRAMs will automatically enable the DLL when the device returns from a low power state to an active state. For example, DDR SDRAMs support a self-refresh mode similar to the same mode in SDR SDRAMs. In this mode, an internal refresh circuit keeps the memory refreshed so that data is not lost while the interface to the RAM controller remains idle.

Some embodiments of the device depicted in FIG. 1 may make use of this self-refresh mode when the DDR SDRAM is not being used actively. In that case, the DDR SDRAM controller may issue a Mode Register Set command in order to disable the DLL when the device re-enters an active mode, thereby avoiding the 200 cycle DLL lock time and allowing the non-periodic clocking method of FIG. 3 to be used.

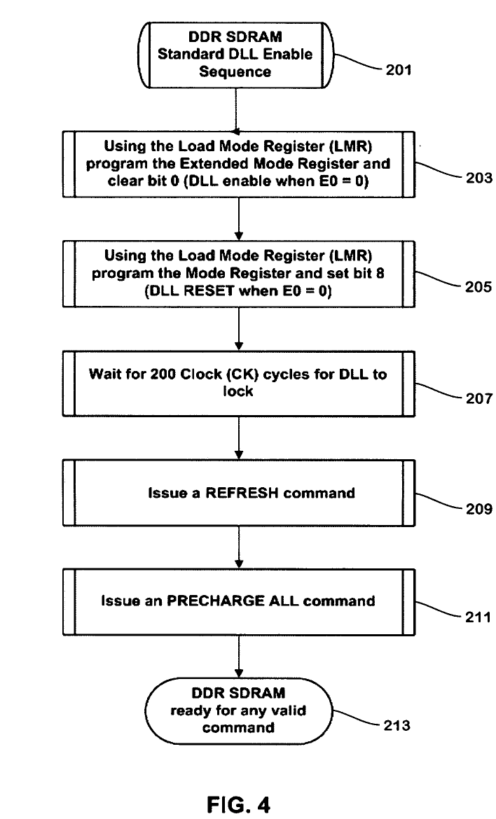

In the event that the system requires DDR SDRAM bandwidth which is greater than that provided in the low power mode with the DLL of the DDR SDRAM disabled, a higher performance mode can be achieved by re-enabling the DLL of the DDR SDRAM and by performing a DLL RESET sequence. FIG. 4 demonstrates one particular, non-limiting method by which the DLL of the DDR SDRAM may be re-enabled in this manner.

In the method depicted in FIG. 4, the DLL of the DDR SDRAM is enabled 201 and initialized by issuing a Load Mode Register command for the Extended Mode Register (BA0 and BA1 are asserted low and high, respectively), while clearing bit 0 of this register 203, thereby enabling the DLL of the DDR SDRAM. This is followed by issuance of another Load Mode Register command 205 to the Mode Register (where BA0 and BA1 are both asserted low) while setting bit 8 to reset the DLL of the DDR SDRAM. The DLL reset requires performing 200 NOP or DESELECTS cycles 207 to ensure that enough clock cycles have occurred, thereby ensuring that the worst case DLL lock time of the DDR SDRAM is met. This sequence is then followed by two AUTO REFRESH commands 209 and a PRECHARGE ALL command 211. At this point, the DDR SDRAM is ready 213 for high speed clock command accesses up to its rated maximum access speed.

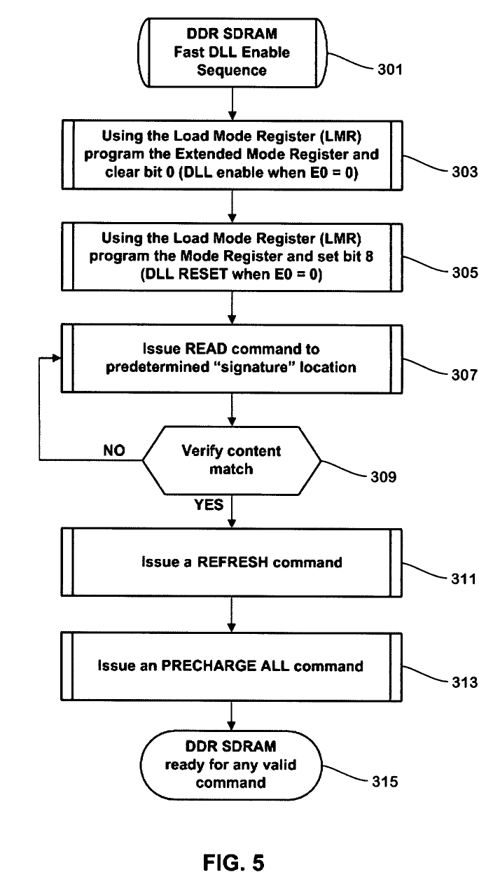

FIG. 5 illustrates a further particular, non-limiting embodiment of a method by which the DLL of the DDR SDRAM may be more time efficiently re-enabled. As in the previously described embodiment, the DLL of the DDR SDRAM is enabled 301 and initialized by issuing a Load Mode Register command for the Extended Mode Register (BA0 and BA1 are asserted low and high, respectively), while clearing bit 0 of this register 303, thereby enabling the DLL of the DDR SDRAM. This is followed by issuance of another Load Mode Register command 305 to the Mode Register (where BA0 and BA1 are both asserted low) while setting bit 8 to reset the DLL of the DDR SDRAM.

During initial start-up of the system, a reserved “signature” memory location is initialized with a predetermined value. However, unlike the previous embodiment in which 200 NOP or DESELECT cycles are performed (this is done to ensure worst case DLL lock time when the system requires switching from a low power mode where the DLL of the DDR SDRAM is disabled, to one of a higher performance mode where the DLL of the DDR SDRAM must be re-enabled and reset), the system will instead perform a read cycle 307 of the “signature” memory location in a loop until the predetermined value is correctly accessed, as gauged by content match verification 309. As in the previous embodiment, this sequence is then followed by two AUTO REFRESH commands 311 and a PRECHARGE ALL command 313. At this point, the DDR SDRAM is ready 315 for high speed clock command accesses up to its rated maximum access speed. This process will typically yield a DLL lock well under the worst case 200 NOP cycles, thereby providing for a much faster memory access speed switch.

While the devices and methodologies disclosed herein have been described primarily with reference to embodiments in which a host device causes a DLL to be disabled or re-enabled so as to switch a memory device between first and second operational states, it will be appreciated that similar means may be utilized to reduce power consumption in the memory device without departing from the teachings herein. For example, in some embodiments, the memory device may be equipped with suitable circuitry or algorithms which enable it to sense the operational characteristics of the host device it is incorporated into.

As a specific example, the interface DLL may contain suitable algorithms which permit such identification, and which modify the clock rate of the memory device accordingly. The DLL may also contain various algorithms which permit the memory device to identify different operational modes which the host device may enter, and which permit the memory device to adopt its clock rate accordingly.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A method for reducing the power consumption of a memory device, comprising:
providing a memory device equipped with an interface clock which is controlled by a Delay Locked Loop (DLL) such that the memory device is configured to operate in a first mode characterized by a minimum clock rate Rₘᵢₙ; and
operating the memory device in a second mode by disabling the DLL, wherein the second mode is characterized by a nonzero clock rate R_{c}<Rₘᵢₙ.

2. The method of claim 1, wherein the memory device consumes less power in the second mode than in the first mode.

3. The method of claim 1, wherein the memory device is DDR SDRAM.

4. The method of claim 1, wherein the memory device is DDR2 SDRAM.

5. The method of claim 1, wherein the memory device is DDR3 SDRAM.

6. The method of claim 1, further comprising:
providing a clock to the memory device only when access to the memory device is required.

7. The method of claim 6, wherein the memory device is operated asynchronously.

8. The method of claim 1, wherein the memory device is equipped with a set of control signals and a data bus, wherein the interface clock is characterized by a rising edge and a falling edge, and wherein the set of control signals and data bus are synchronized to the interface clock.

9. The method of claim 1, wherein the memory device is incorporated into a host device, wherein the operation of the memory device is controlled by software, and wherein the software is configured to switch the operation of the memory device between the first and second mode depending on the needs of the host device.

10. The method of claim 5, wherein the memory device is incorporated into a host device, and further comprising:
providing a fast re-lock of the DLL after a DLL reset sequence is performed.

11. The method of claim 10, further comprising:
performing a READ loop until a predetermined signature value is read and verified indicating that the DLL is locked, thereby allowing for DLL re-lock of the memory device.

12. The method of claim 11, wherein the DLL of the memory device is enabled and reset without having to undergo multiple DESELECT cycles prior to DLL re-lock.

13. The method of claim 11, wherein the DLL of the memory device is enabled and reset without having to undergo multiple NOP cycles prior to DLL re-lock.

14. A portable electronic device, comprising:
a memory device equipped with an interface clock and a Delay Locked Loop (DLL) such that the memory device is configured to operate in a first mode characterized by a minimum clock rate Rₘᵢₙ; and
a controller adapted to cause the memory device to operate in a second mode by disabling the DLL, wherein the second mode is characterized by a nonzero clock rate R_{c}<Rₘᵢₙ.

15. The device of claim 14, wherein the controller is a solid state device.

16. The device of claim 14, wherein the controller comprises a software program.

17. The device of claim 14, wherein the memory device consumes less power in the second mode than in the first mode.

18. The method of claim 1, wherein the memory device is DDR SDRAM.

19. The device of claim 14, wherein the memory device is DDR2 SDRAM.

20. The device of claim 14, wherein the memory device is DDR3 SDRAM.

21. The device of claim 14, wherein the controller is adapted to provide a clock to the memory device only when access to the memory device is required.

22. The device of claim 21, wherein the device operates the memory device in an asynchronous manner.

23. The device of claim 14, wherein the memory device is equipped with a set of control signals and a data bus, wherein the interface clock is characterized by a rising edge and a falling edge, and wherein the set of control signals and data bus are synchronized to the interface clock.

24. The device of claim 14, wherein the memory device is incorporated into a host device, wherein the operation of the memory device is controlled by software, and wherein the software is configured to switch the operation of the memory device between the first and second mode depending on the needs of the host device.

25. The device of claim 14, wherein the memory device is incorporated into a host device, and wherein the DLL is equipped with at least one algorithm for identifying at least one operational characteristic of the host device and for adapting Rₘᵢₙ to the at least one operational characteristic.

26. The device of claim 25, wherein the operational characteristic relates to which of the first and second modes the host device requires the memory device to operate in.

27. The device of claim 20, wherein the memory device is incorporated into a host device, and further comprising:
providing a fast re-lock of the DLL after a DLL reset sequence is performed.

28. The device of claim 25, further comprising:
performing a READ loop until a predetermined signature value is read and verified indicating that the DLL is locked, thereby allowing for DLL re-lock of the memory device.

29. The device of claim 26, wherein the DLL is enabled and reset without having to undergo multiple DESELECT cycles prior to DLL re-lock.

30. The device of claim 26, wherein the DLL is enabled and reset without having to undergo multiple NOP cycles prior to DLL re-lock.

31. A method for providing dynamic clock management in a host device which incorporates DDR SDRAM, the method comprising:
performing a READ loop until a predetermined signature value is read and verified indicating that the DLL is locked, thereby allowing for DLL re-lock of the memory device.

32. The device of claim 31, wherein the DLL is enabled and reset without having to undergo multiple DESELECT cycles prior to DLL re-lock.

33. The device of claim 31, wherein the DLL is enabled and reset without having to undergo multiple NOP cycles prior to DLL re-lock.
